(19) United States
(12) Patent Application Publication
(10) Pub. No.: US 2019/0097655 A1
(43) Pub. Date: Mar. 28, 2019

(54) LOW-DENSITY PARITY-CHECK CODE DECODER AND DECODING METHOD

(71) Applicant: MStar Semiconductor, Inc., Hsinchu Hsien (TW)

(72) Inventor: Yu-Hsien KU, Hsinchu Hsien (TW)

(21) Appl. No.: 15/909,171

(22) Filed: Mar. 1, 2018

(30) Foreign Application Priority Data
Sep. 27, 2017 (TW) 106133090

(51) Int. Cl. H03M 13/11; H03M 13/00

(52) U.S. Cl. CPC H03M 13/1111; H03M 13/116; H03M 13/6502

(57) ABSTRACT

A low-density parity-check (LDPC) code decoding method for decoding a set of initial log likelihood ratio (LLR) outputted by a de-mapping circuit. The decoding method comprises: receiving and storing the set of initial LLR from the de-mapping circuit; receiving and storing the set of initial LLR from a first buffer; receiving the set of initial LLR from a second buffer; performing a decoding operation according to the set of initial LLR to generate a set of intermediate LLR; determining whether the set of intermediate LLR is converged; when the set of intermediate LLR is not converged, storing the set of intermediate LLR back into the second buffer, wherein a storage space of the second buffer is greater than that of the first buffer; and when the set of intermediate LLR is converged, outputting the set of intermediate LLR as a set of decoded LLR.

This application claims the benefit of Taiwan application Serial No. 106133090, filed on Sep. 27, 2017, the subject matter of which is incorporated herein by reference.

### BACKGROUND OF THE INVENTION

### Field of the Invention

The invention relates in general to a decoder, and more particularly to a low-density parity-check (LDPC) code decoder and decoding method.

### Description of the Related Art

The decoding operation of low-density parity-check (LDPC) codes involves large amounts of data. Even quasi-cyclic low-density parity-check (QC-LDPC) codes having a relatively lower computation amount still bring a hardware cost burden on an LDPC code decoder. In the current market where chip volume and circuit costs are extremely sensitive, maintaining circuit performance and at the same time reducing chip volume and circuit costs are a big challenge.

### SUMMARY OF THE INVENTION

In view of issues of the prior art, it is an object of the present invention to provide a low-density parity-check (LDPC) code decoder and decoding method so as to reduce both chip volume and circuit costs.

The present invention provides an LDPC code decoder for de-mapping a set of initial log likelihood ratio (LLR) outputted by a de-mapping circuit. The decoder includes a first buffer, a second buffer and a decoding circuit. The first buffer receives and stores the set of initial LLR from the de-mapping circuit. The second buffer receives and stores the set of initial LLR from the first buffer. The decoding circuit performs steps of: receiving the set of initial LLR from the second buffer; performing a decoding operation according to the set of initial LLR to calculate a set of intermediate LLR, wherein a data size of the set of intermediate LLR is larger than that of the set of initial LLR; determining whether the set of intermediate LLR is converged; when it is determined that the set of intermediate LLR is not yet converged, storing the set of intermediate LLR back into the second buffer, wherein a storage space of the second buffer is greater than that of the first buffer; and when it is determined that the set of intermediate LLR is converged, outputting the set of intermediate LLR as a set of decoded LLR.

The present invention further discloses a low-density parity-check (LDPC) code decoding method for decoding a set of initial log-likelihood ratio (LLR) outputted by a de-mapping circuit. The decoding method includes: receiving and storing the set of initial LLR from the de-mapping circuit; receiving and storing the set of initial LLR from a first buffer; receiving the set of initial LLR from a second buffer; performing a decoding operation according to the set of initial LLR to generate a set of intermediate LLR, wherein a data size of the set of intermediate LLR is larger than that of the set of initial LLR; determining whether the set of intermediate LLR is converged; when it is determined that the set of intermediate LLR is not yet converged, storing the set of intermediate LLR back into the second buffer, wherein a storage space of the second buffer is greater than that of the first buffer; and when it is determined that the set of intermediate LLR is converged, outputting the set of intermediate LLR as a set of decoded LLR.

The above and other aspects of the invention will become better understood with regard to the following detailed description of the non-limiting embodiments. The following description is made with reference to the accompanying drawings.

### BRIEF DESCRIPTION OF THE DRAWINGS

FIG. 1 is a block diagram of a low-density parity-check (LDPC) code decoder;

FIG. 2 is a block diagram of an LDPC code decoder according to an embodiment of the present invention; and

FIG. 3 is an LDPC code decoding method according to an embodiment of the present invention.

### DETAILED DESCRIPTION OF THE INVENTION

The disclosure of the application includes a low-density parity-check (LDPC) code decoder and decoding method applicable to a receiving end of a communication system. In possible implementation, one person having ordinary skills in the art can choose equivalent elements or steps based on the disclosure of the application to achieve the present invention; that is, the implementation of the present invention is not limited to the embodiments below.

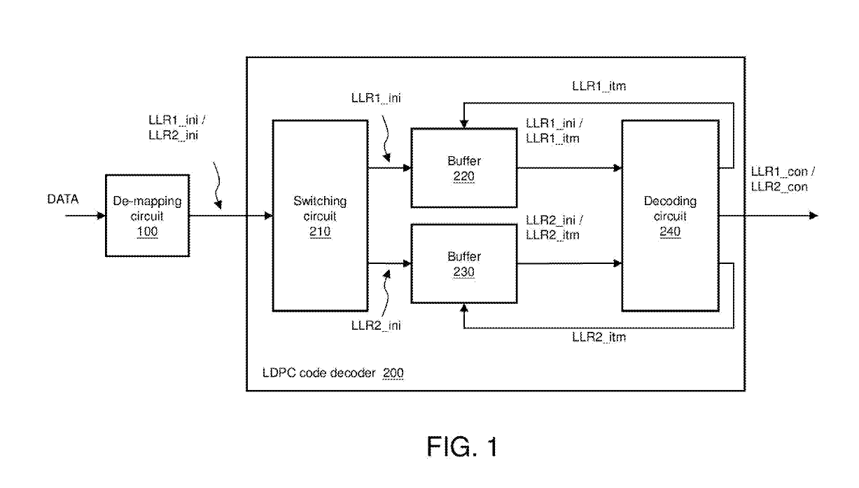

FIG. 1 shows a block diagram of an LDPC code decoder 200. The LDPC code decoder 200 is applicable to decoding operations of LDPC codes or decoding operations of quasi-cyclic low-density parity-check (QC-LDPC) codes.

A de-mapping circuit 100 performs de-mapping on data DATA to sequentially generate multiple sets of log likelihood ratios (LLR) LLR1_ini and LLR2_ini. After performing a decoding operation on the multiple sets of LLR LLR1_ini and LLR2_ini, the LDPC code decoder 200 generates multiple sets of decoded LLR LLR1_con and LLR2_con, respectively. A back-end circuit (not shown) of the LDPC code decoder 200 can obtain, according to the multiple sets of decoded LLR LLR1_con and LLR2_con, original data before a transmitting end performs encoding.

More specifically, the LDPC code decoder 200 includes a switching circuit 210, buffers 220 and 230, and a decoding circuit 240. The switching circuit 210 receives the multiple sets of initial LLR LLR1_ini and LLR2_ini from the de-mapping circuit 100, and outputs multiple sets of initial LLR LLR1_ini and LLR2_ini to one of the buffers 220 and 230. For example, the switching circuit 210 stores the set of initial LLR LLR1_ini into the buffer 220. The decoding circuit 240 then reads the set of initial LLR LLR1_ini from the buffer 220 to perform an iteration operation to generate a set of intermediate LLR LLR1_itm, and determines whether the set of intermediate LLR LLR1_itm is converged. When the decoding circuit 240 determines that the set of intermediate LLR LLR1_itm is not converged, the decoding circuit 240 stores the set of intermediate LLR LLR1_itm back into the buffer 220, and performs a next decoding operation. When the decoding circuit 240 determines that, after multiple decoding operations (i.e., an iteration operation), the set of intermediate LLR LLR1_itm is converged, the decoding circuit 240 outputs the set of intermediate LLR LLR1_itm as the set of decoded LLR LLR1_con. At this point, the decoding circuit 240 has completed the decoding operation with respect to the set of initial LLR LLR1_ini.

When the decoding circuit 240 has not yet completed the decoding operation with respect to the set of initial LLR LLR1_ini and the de-mapping circuit has already generated the next set of initial LLR LLR2_ini, the switching circuit 210 outputs the next set of initial LLR LLR2_ini into the other buffer 230, so as to prevent the decoding operation that the decoding circuit 240 performs on the set of initial LLR LLR1_ini from being affected. After having completed the decoding operation with respect to the set of initial LLR LLR1_ini, the decoding circuit 240 can then read the next set of initial LLR LLR2_ini from the buffer 230 to perform a decoding operation. Similarly, the decoding circuit 240 continues the decoding operation on the set of initial LLR LLR2_ini, and when the set of intermediate LLR LLR2_imt is converged, the decoding circuit 240 outputs the set of converged intermediate LLR LLR2_itm as the next set of decoded LLR LLR2_con, and so forth. In other words, the LDPC code decoder 200 alternately stores the initial LLR received from the de-mapping circuit 100 into the buffers 220 and 230 to perform the decoding operation.

It should be noted that, the de-mapping circuit 100, the switching circuit 210 and the decoding circuit 240 can usually be implemented by dedicated hardware circuits, but can also be implemented by software programs. Further, the de-mapping circuit 100, the switching circuit 210 and the decoding circuit 240 are generally known to one person skilled in the art, and associated details shall be omitted herein.

In general, as the number of decoding operations performed by the decoding circuit 240 increases, the data size of an LLR also increases. More specifically, the data sizes of the intermediate LLR LLR1_itm and LLR2_itm are larger than those of the initial LLR LLR1_ini and LLR2_ini, and continue to become larger as the number of decoding operations performed thereon increases. Because the buffers 220 and 230 are both used to store the non-converged intermediate LLR LLR1_itm and LLR2_itm, the storage spaces of the buffers 220 and 230 need to sufficient for storing a maximum LLR LLR1_itm or LLR2_itm (i.e., one last set of non-converged intermediate LLR LLR1_itm or LLR2_itm). For example, the data sizes of the LLR LLR1_ini and LLR2_ini are 6 bits. As the number of decoding operations increases, the data sizes of the intermediate LLR LLR1_itm and LLR2_itm may be between 6 bits and 10 bits, and the data sizes of the decoded LLR LLR1_con and LLR2_con may be 10 bits. Thus, the storage spaces of the buffers 220 and 230 are designed to be 10 bits, for example.

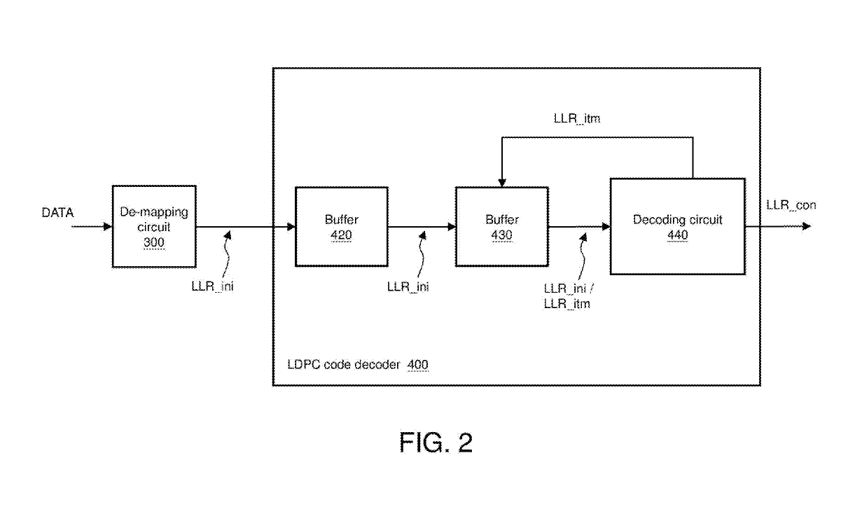

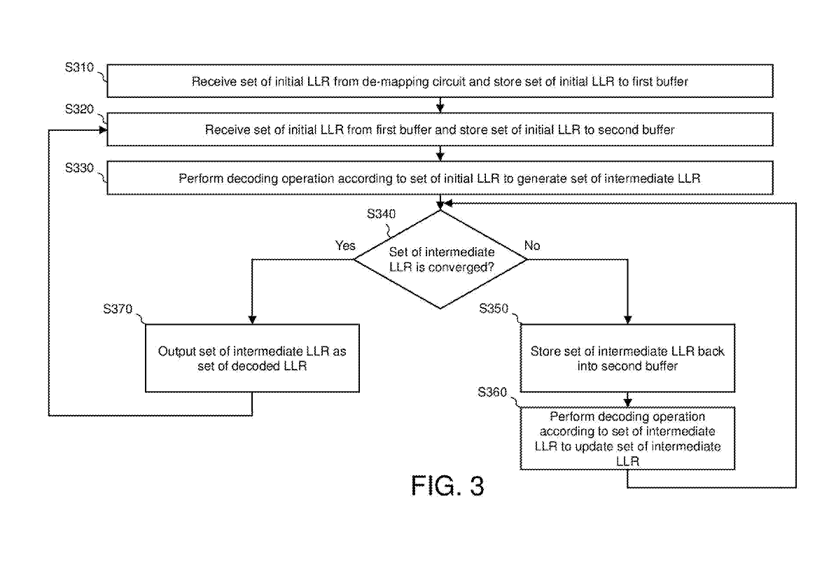

FIG. 2 shows a block diagram of an LDPC code decoder according to an embodiment of the present invention. FIG. 3 shows a flowchart of an LDPC code decoding method according to an embodiment of the present invention. An LDPC code decoder 400 is applicable to decoding operations of LDPC codes or decoding operations of QC-LDPC codes. The LDPC code decoder 400 includes buffers 420 and 430, and a decoding circuit 440. The buffer 420 receives and stores a set of initial LLR LLR_ini from a de-mapping circuit 300 (step S310). It should be noted that, operation details of the de-mapping circuit 300 can be referred from the details in the description associated with the de-mapping circuit 100 above, and shall be omitted herein. Next, the buffer 430 receives and stores the set of initial LLR LLR_ini from the buffer 420 (step S320). The decoding circuit 440 then receives the set of initial LLR LLR_ini from the buffer 430, and performs an iteration operation according to the set of initial LLR LLR_ini to generate a set of decoded LLR LLR_con. More specifically, the decoding circuit 440 first performs a decoding operation on the set of initial LLR LLR_ini to generate a set of intermediate LLR LLR_itm (step S330), and determines whether the set of intermediate LLR LLR_itm is converged (step S340). When the decoding circuit 440 determines that the set of intermediate LLR LLR_itm is not yet converged, the decoding circuit 440 stores the set of intermediate LLR LLR_itm back into the buffer 430 (step S350). Next, the decoding circuit 440 receives the set of intermediate LLR LLR_itm from the buffer 430, and performs a next decoding operation according to the set of intermediate LLR LLR_itm to update the set of intermediate LLR LLR_itm (step S360). When the decoding circuit 440 determines that the set of intermediate LLR LLR_itm, after multiple decoding operations (i.e., the iteration operation), is converged, the decoding circuit 440 outputs the set of converged intermediate LLR LLR_itm as the set of decoded LLR LLR_con (step S370). At this point, the decoding circuit 440 has completed the decoding operation with respect to the set of initial LLR LLR_ini.

In one embodiment, after the buffer 430 receives and stores the set of initial LLR LLR_ini from the buffer 420 (step S320), the buffer 420 receives and stores a next initial LLR from the de-mapping circuit (step S310). More specifically, while any of steps S330 to S370 is being performed, the buffer 420 can receive and store the next set of initial LLR from the de-mapping circuit 300. After the decoding circuit 440 has completed the decoding operation on the set of the initial LLR LLR_ini, the buffer 430 can then receive and store the next set of initial LLR from the buffer 420 (step S320). The decoding circuit 440 then receives the next set of initial LLR from the buffer 430, and performs an iteration operation on the next set of initial LLR to generate a next set of decoded LLR (repeating steps S330 to S370).

Under the above design, only the buffer 430 stores the set of intermediate LLR LLR_itm having a data size that gradually increases as the number of decoding operations increases, and the buffer 420 stores only the set of initial LLR LLR_ini but not the set of intermediate LLR LLR_itm having a data size that gradually increases as the number of decoding operations increases. Therefore, the storage space of the buffer 420 can be smaller than that of the buffer 430. For example, the data size of the set of intermediate LLR LLR_itm is 6 bits, the data size of the set of intermediate LLR LLR_itm that gradually increases as the number of decoding operations increases is between 6 bits and 10 bits, and the data size of the set of decoded LLR LLR_con is 10 bits. Thus, the storage space of the buffer 430 is designed as 10-bit, and the storage space of the buffer 420 is designed as 6-bit or 7-bit, for example.

Compared to the LDPC code decoder 200 that uses two buffers 220 and 230 having relatively larger storage spaces (e.g., 10-bit), the LDPC code decoder 400 can use one buffer 430 having a larger storage space (e.g., 10-bit) and one buffer 430 having a smaller storage space (e.g., 6-bit) to achieve the same function. In other words, the LDPC code decoder and decoding method of the present invention are capable of efficiently utilizing buffers to perform decoding operations of LDPC codes, reducing both chip volume and circuit costs and providing products with better competitiveness.

One person skilled in the art can understand implementation details and variations of the method of the present invention based on the disclosure on the device of the present invention. While the invention has been described by way of example and in terms of the embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A low-density parity-check (LDPC) code decoder, for de-mapping a set of initial log-likelihood ratio (LLR) outputted by a de-mapping circuit, the decoder comprising:
a first buffer, receiving and storing the set of initial LLR from the de-mapping circuit;
a second buffer, receiving and storing the set of initial LLR from the first buffer; and
a decoding circuit, performing steps of:
receiving the set of initial LLR from the second buffer;
performing a decoding operation on the set of initial LLR to calculate a set of intermediate LLR, wherein a data size of the set of intermediate LLR is larger than that of the set of initial LLR;
determining whether the set of intermediate LLR is converged;
when it is determined that the set of intermediate LLR is not yet converged, storing the set of intermediate LLR back into the second buffer, wherein a storage space of the second buffer is greater than that of the first buffer; and
when it is determined that the set of intermediate LLR is converged, outputting the set of intermediate LLR as a set of decoded LLR.

2. The LDPC code decoder according to claim 1, wherein the first buffer does not store the set of intermediate LLR.

3. The LDPC code decoder according to claim 2, wherein the storage space of the first buffer is equal to the data size of the set of initial LLR.

4. The LDPC code decoder according to claim 1, wherein, after the second buffer receives the set of initial LLR from the first buffer, the first buffer receives and stores a next set of initial LLR from the de-mapping circuit.

5. A low-density parity-check (LDPC) code decoding method, for de-mapping a set of initial log likelihood ratio (LLR) outputted by a de-mapping circuit, the decoding method comprising:
receiving and storing the set of initial LLR from the de-mapping circuit;
receiving and storing the set of initial LLR from the first buffer;
receiving the set of initial LLR from the second buffer;
performing a decoding operation on the set of initial LLR to calculate a set of intermediate LLR, wherein a data size of the set of intermediate LLR is larger than that of the set of initial LLR;
determining whether the set of intermediate LLR is converged;
when it is determined that the set of intermediate LLR is not yet converged, storing the set of intermediate LLR back into the second buffer, wherein a storage space of the second buffer is greater than that of the first buffer; and
when it is determined that the set of intermediate LLR is converged, outputting the set of intermediate LLR as a set of decoded LLR.

6. The LDPC code decoding method according to claim 6, wherein the first buffer does not store the set of intermediate LLR.

7. The LDPC code decoding method according to claim 6, wherein the storage space of the first buffer is equal to the data size of the set of initial LLR.

8. The LDPC code decoding method according to claim 5, further comprising:
after the second buffer receives the set of initial LLR from the first buffer, receiving a next set of initial LLR from the de-mapping circuit, and storing the next set of initial LLR to the first buffer.
